(19) United States
(12) Patent Application Publication
(10) Pub. No.: US 2007/0123045 A1
(43) Pub. Date: May 31, 2007

(54) Method for the treatment of material, in particular in the fabrication of semiconductor components

(76) Inventors: Stephan Wege, Dresden (DE); Joachim Schlor, Dresden (DE)

Correspondence Address: SLATER & MATSIL LLP, 17950 PRESTON ROAD, SUITE 1000, DALLAS, TX, 75252, US

(21) Appl. No.: 11/605,730

(22) Filed: Nov. 28, 2006

Related U.S. Application Data
(60) Provisional application No. 60/740,814, filed on Nov. 30, 2005.

(51) Int. Cl. H01L 21/302

(52) U.S. Cl. 438/689

(57) ABSTRACT

In a method for the treatment of material, in particular in the fabrication of semiconductor components, at least one partial region of the material is implanted with ions in a targeted manner. Afterward or in a later method step, a step of etching the material is performed, the etching rate of this method step being altered in a targeted manner by the implanted ions.

This application claims the benefit of U.S. Provisional Application No. 60/740,814, filed on Nov. 30, 2005, entitled “Method for the Treatment of Material, in Particular in the Fabrication of Semiconductor Components,” which application is hereby incorporated herein by reference.

### TECHNICAL FIELD

The invention relates to a method for the treatment of material, for example, in the fabrication of semiconductor components.

### BACKGROUND

For the fabrication of semiconductor components, an etching step (e.g., dry etching step, wet etching step) is used for many process steps. In this case, the etching of a material is effected on the basis of atoms or molecules from a gas and/or by bombarding the material surface to be etched with ions (as, e.g., in the case of RIE or Reactive Ion Etching).

In this case, the etching rate of the dry etching process steps is generally a function of the material and the process parameters chosen (e.g., ion species, pressure, power, form and strength of the field, etc.). In this case, the profiling is essentially determined by way of the process parameters or the mask.

Since the structures to be etched in the material are becoming ever smaller and deeper (that is to say the aspect ratio is increasing to an ever greater extent), the etching medium cannot perform effective etching everywhere; that is to say that the etching rate is limited. The influencing of the etching rate by the process parameters or the apparatuses encounters limits.

### SUMMARY OF THE INVENTION

In various embodiments, the present invention provides a method in which the etching rate can be influenced better.

Firstly, at least one partial region of a material is implanted with ions in a targeted manner, and afterward or in a later method step, an etching step is performed, the etching rate of this method step being altered in a targeted manner by the implanted ions. Properties of the material can be influenced in a targeted manner by the ion implantation, so that the subsequent etch can be performed more efficiently. In this case, the etch may advantageously be embodied as a dry etch or wet etch.

In this case, it is advantageous if the implantation of the ions in at least one partial region of the material results in the creation of a deposit of the atoms or molecules, so that the same ions are available as reactant or inhibitor for the subsequent dry etching step. In this case, the deposit serves, e.g., as a store for reactants or inhibitors at locations that are otherwise difficult for reactive etching media to access.

It is furthermore advantageous if the implantation of the ions in the at least one partial region of the material results in the crystalline structure of the material being changed in a targeted manner for influencing the etching rate.

It is an advantageous procedure for the implantation if the spatial arrangement of the implanted ions, in particular in the form of a deposit in the material, is controlled in a targeted manner by the implantation angle. By way of the choice of implantation angle, even regions that are difficult to access, e.g., walls of a trench, can be reached for the ion implantation.

If the geometry to be implanted is complex, e.g., has a depression, it is advantageous if a rotational relative movement is produced between the material and the implantation source, so that an implantation can be performed in particular also in vertical regions (e.g., walls) of the material.

It is also advantageous if the implantation depth of the ions in the material and/or the form of the implanted partial region is controlled in a targeted manner by the setting of the implantation energy. One possible value for the implantation energy is, e.g., 2 keV. However, it is also possible to use higher values (e.g., 30 keV).

In this case, it may be particularly advantageous if the extent and/or form of the implanted partial region in the material is controlled by a time control of the ion implantation, a control of the ion current density and/or a control of the ion energy. If a desired implantation profile in the material is known, then the time control of the ion implantation, the control of the ion current density and/or the control of the ion energy may advantageously be effected in a manner dependent on this previously selected concentration profile in the partial region. The diffusion behavior of an ion species in a material is known, so that a temperature and/or time control can be used to define, e.g., how many ions are implanted and which regions achieve a specific concentration in this case.

Since diffusion processes are temperature-dependent, it is advantageous if the implantation of the ions is controlled by a targeted temperature regulation of the material.

It is also advantageous if the implantation is controlled in a targeted manner by a suitable mask, in particular resist mask.

In a further advantageous refinement, ions are implanted at least partly at the bottom of a depression in particular of a deep trench.

It is also advantageous if the ions are implanted at least partly in a wall of a depression in the material, in particular of a deep trench. In this case it is particularly advantageous if the implantation in the wall is effected by an implantation at an implantation angle α of greater than or equal to 0° measured with respect to the vertical with respect to the material. It is also advantageous if the implantation in the wall is effected by rotation of the material and/or rotation of the ion source at a plurality of locations of the depression.

Nitrogen ions, oxygen ions and/or halogen ions, in particular fluorine ions or chlorine ions, are advantageously used as implanted ions. In this case, an implantation with oxygen and/or nitrogen ions is particularly suitable for producing an etching stop layer. The implantation with fluorine and/or chlorine ions is suitable for forming a deposit.

An advantageous purpose for use of the method according to the invention is if the material is silicon of a substrate for the fabrication of DRAM chips or logic chips.

### BRIEF DESCRIPTION OF THE DRAWINGS

The invention is explained in more detail below using a plurality of exemplary embodiments with reference to the figures of the drawings, in which:

FIGS. 1A and 1B show an implantation of an etching stop layer as a first exemplary embodiment of the method according to the invention;

FIGS. 2A, 2B and 2C show a reactant implantation as a second exemplary embodiment of the method according to the invention;

FIGS. 3A, 3B and 3C show a reactant/inhibitor implantation as a third exemplary embodiment of the method according to the invention; and

FIGS. 4A and 4B show a reactant implantation with concentration profile as a fourth exemplary embodiment of the method according to the invention.

The following list of reference symbols can be used in conjunction with the figures:
1 Partial region of a material, e.g., in a substrate
2 Ions for implantation
3 Deposit of the ions
5 Depression (deep trench)
6 Wall
7 Bottom of the depression
8 Accumulation of the ions in the depression
10 Material
11 Further deposited layer
12 Depression
13 Mask layer
α Implantation angle

### DETAILED DESCRIPTION OF ILLUSTRATIVE EMBODIMENTS

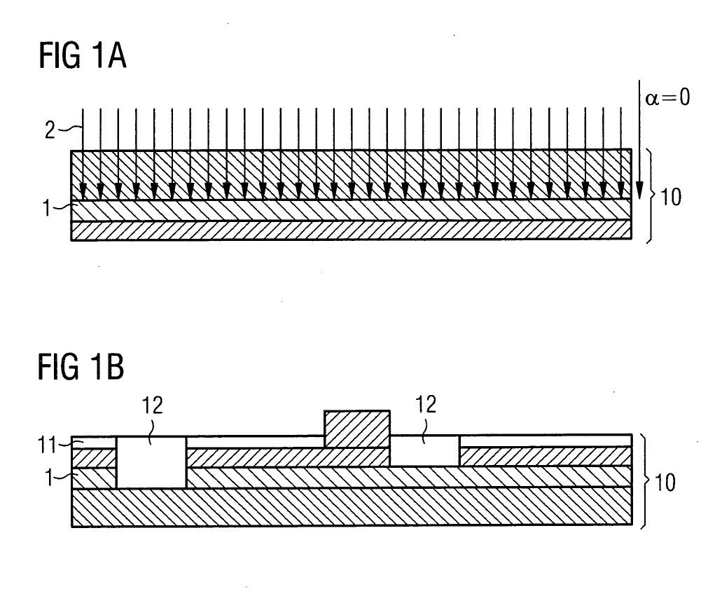

FIG. 1A illustrates the implantation of a material 10 with ions 2 as a first process step. The ion implantation is carried out here with nitrogen, which penetrates through the material 10, here silicon, and is incorporated in a partial region 1 of the material in a manner dependent on the kinetic energy of the ions 2. The depth of incorporation is determined depending on the kinetic energy of the ions 2. The implantation angle α is 0° here since the implantation is effected perpendicularly to the material 10.

In the present example, no mask is arranged above the material 10, so that the ions 2 are implanted over the entire surface. The kinetic energy of the ions 2 determines the depth (that is to say the range of the ions in the material) at which a layer forms.

In subsequent method steps, which are not illustrated in detail here, inter alia a further layer 11 is applied to the material (see FIG. 1B), and is then patterned by means of a dry etching step (here by means of RIE). Depressions 12 are etched in the process. In principle, however, the etch may also be effected by means of a wet-chemical etching step.

The etching of the depressions 12 is stopped at the partial region 1 with the implanted ions 2 since the previous implantation has changed the material 10 here in such a way that the etching is selective with respect to the partial region 1.

In this embodiment, an etching stop layer is produced in a targeted manner without a particular layer having to be deposited on a substrate for this purpose.

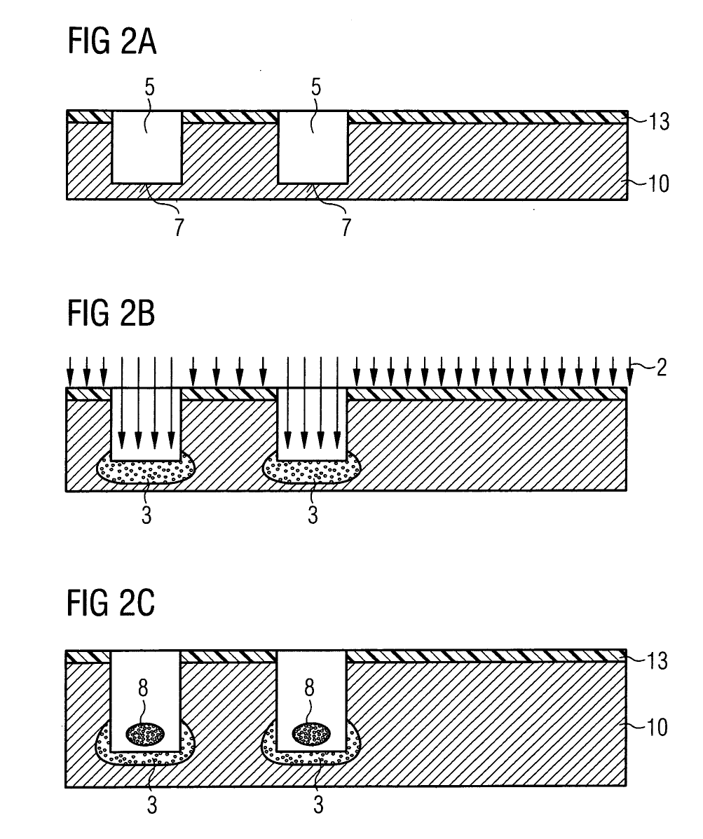

FIGS. 2A, 2B and 2C illustrate a second embodiment, in which the targeted alteration of the material 10 by means of ion implantation has a different effect.

FIG. 2A illustrates as initial situation a material 10 (here silicon again) with two depressions 5. The depressions 5 had been fabricated in a preceding first etching step by means of the mask layer 13. The aspect ratio of the depression is not depicted to scale here for reasons of clarity. The aspect ratio is usually greater than ten. The first etching step is performed until the etching rate permits a practical progress in the depth of the depression. In order to improve the etching progress use is then made of the second embodiment of the invention.

In FIG. 2B, an implantation is performed by means of ions 2 at an implantation angle α=0°. Halogen ions, in particular fluorine or chlorine ions, are used here.

The ions 2 do not settle in the mask layer 13, but rather at the bottom 7 of the depression 5. A deposit 3 of atoms or molecules forms in this partial region of the material 10.

Instead of a continuous layer as in the first exemplary embodiment, a local accumulation of the ions 2 at the bottom 7 of the depression 5 is achieved here.

After the accumulation has taken place, the etching is continued with a second dry etching step. The atoms or molecules in the deposit 3 are uncovered in the process and are available as reactants at the bottom of the depression during the etch, illustrated by the accumulation 8 in the depression 5 in FIG. 2C. A more uniform etch is possible with these reactants that have been additionally made available.

The first and the second dry etching step may, but need not, be performed by means of the same method.

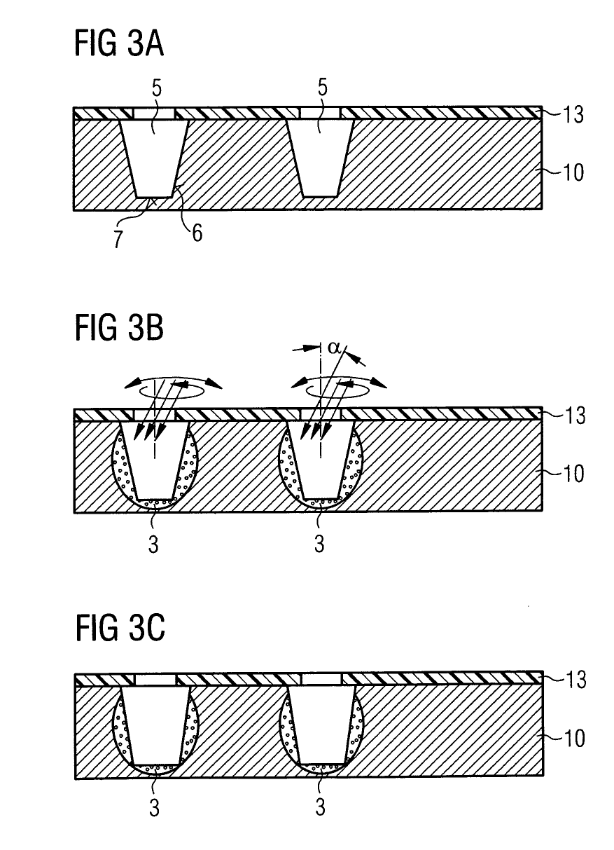

FIGS. 3A, 3B and 3C describe a third embodiment of the method according to the invention. In a similar manner to the initial situation in accordance with FIG. 2A, here as well a depression 5 is produced in a material 10 by means of a mask layer 13. However, here the first etching step is performed in the form of a wet etch. An undercut of the mask layer 13 has formed in the process.

The undercut depression 5 is intended to be extended, with the result that the walls 6 of the depressions 5 have to be treated. For this purpose, an ion implantation is carried out at an implantation angle α=30°. With an oblique implantation, however, only one wall 6 of the depression 5 would be exposed to the implantation. For a uniform implantation, the substrate is rotated and/or pivoted, which is indicated by the arrows. As an alternative or in addition, the implantation source may also be caused to rotate.

The implantation radiation thus sweeps over the walls 6 of the depressions 5. The implantation angle a is chosen in such a way that a sufficient implantation is also effected in the bottom 7 of the depression.

At the end of the implantation, at the walls 6 and at the bottom 7 of the depression 5 a partial region 3 has formed in the material 10, in which the implanted ions 2 have altered the material 10 in a targeted manner, so that a subsequent dry etch (see FIG. 3C) can effect an expansion of the depression 5 in a targeted manner here.

In principle, the etch may also be performed obliquely and with a rotating table for the material.

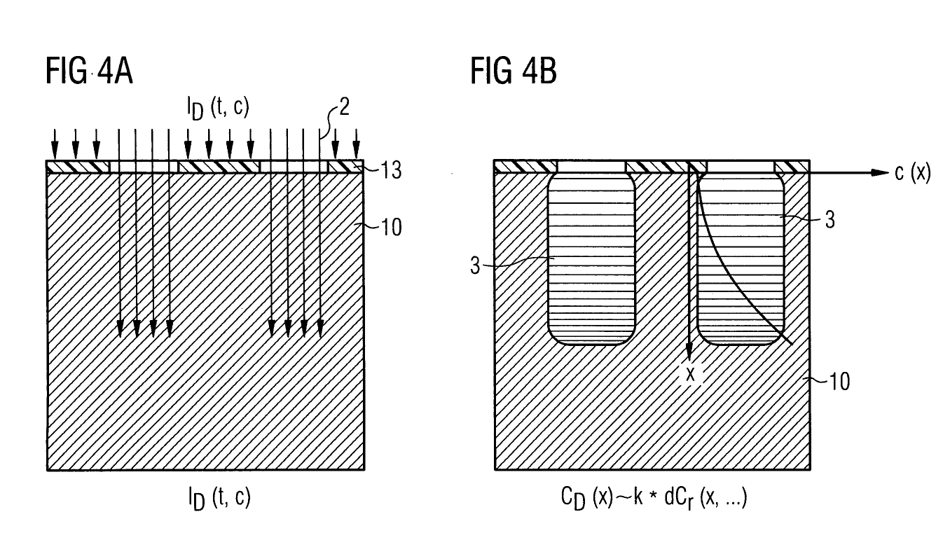

FIGS. 4A and 4B illustrate that the form of the implanted partial region 3 can be controlled in a targeted manner through a setting of the ion current density (implanting intensity I_{D}).

The propagation of the ions in the material 10 is usually subject to Fick's law, that is to say that the concentration profile formed at a constant implantation energy is an error function in the one-dimensional and idealized case (as illustrated in the x direction in FIG. 4B). In monocrystalline materials, e.g., silicon, however, there are preferred directions for the diffusion (channeling). The implantation can be improved by applying a screen layer, e.g., made of oxide, on the surface of the material 10.

Since this propagation is known, it is possible conversely for the implantation energy to be controlled in such a way that, e.g., a constant concentration profile (see block-shaped partial region in FIG. 4B) forms in the material 10. For this purpose, the implantation energy will be high at the beginning, but then fall slowly. In principle, other profiles are also conceivable by controlling the implantation energy.

The dopant concentration C_{D} (that is to say the concentration of the implanted ions) may be chosen proportionally to the change in the desired etching reactant concentration Cᵣ in order to exhibit a desired effect during the subsequent dry etching step.

This consideration presupposes that the temperature during the implantation (also during the diffusion) is constant. Since the diffusion is also temperature-dependent, it is possible to use a temperature control as an alternative or in addition to the time-dependent control of the kinetic energy of the implantation. A higher temperature would more likely promote the diffusion and cooling would more likely prevent it.

The relationships that have been described here in connection with FIGS. 4A and 4B can, of course, also be applied to the other embodiments alone or in combination.

The embodiment of the invention is not restricted to the preferred exemplary embodiments specified above. Rather, a number of variants are conceivable that make use of the method according to the invention also in the case of embodiments of fundamentally different configuration.

What is claimed is:

1. A method for treating a material, the method comprising:
implanting at least one partial region of the material with ions in a targeted manner; and
after implanting the at least one partial region, etching the material, wherein an etching rate of the etching is altered in a targeted manner by the implanted ions.

2. The method as claimed in claim 1, wherein the etching step is embodied as a dry etching step or wet etching step.

3. The method as claimed in claim 1, wherein implanting with ions in the at least one partial region of the material results in creation of a deposit of atoms or molecules, so that the ions are available as reactant or inhibitor for a subsequent etching step.

4. The method as claimed in claim 1, wherein implanting with ions in the at least one partial region of the material results in a crystalline structure of the material being changed in a targeted manner for influencing the etching rate.

5. The method as claimed in claim 1, wherein a spatial arrangement of the implanted ions is controlled in a targeted manner by an implantation angle of the implanting.

6. The method as claimed in claim 1, wherein implanting comprises implanting from an implantation source, wherein a rotational relative movement is produced between the material and the implantation source, so that an implantation can be performed in vertical regions of the material.

7. The method as claimed in claim 1, wherein an implantation depth of the ions in the material and/or form of the implanted partial region is controlled in a targeted manner by setting of an implantation energy.

8. The method as claimed in claim 1, wherein an extent and/or a form of the implanted partial region in the material is controlled by a time control of the implanting, a control of ion current density and/or a control of ion energy.

9. The method as claimed in claim 8, wherein the time control, the control of the ion current density and/or the control of the ion energy is effected in a manner dependent on a previously selected concentration profile of the implanted ions in the at least one partial region.

10. The method as claimed in claim 1, wherein the implanting with ions is controlled by a targeted temperature regulation of the material.

11. The method as claimed in claim 1, wherein the implanting is controlled in a targeted manner by a resist mask or an oxide hard mask.

12. The method as claimed in claim 1, further comprising forming at least one etching stop layer in the material by implanting with oxygen, nitrogen and/or carbon.

13. The method as claimed in claim 1, wherein the ions are implanted at least partly at the bottom of a depression.

14. The method as claimed in claim 1, wherein the ions are implanted at least partly in a wall of a depression in the material.

15. The method as claimed in claim 14, wherein the implantation in the wall is effected by an implantation at an implantation angle α of greater than or equal to 0° measured with respect to a vertical with respect to the material.

16. The method as claimed in claim 15, wherein the implantation in the wall is effected by rotation of the material and/or rotation of an ion source at a plurality of locations of the depression.

17. The method as claimed in claim 1, wherein the implanted ions comprise nitrogen ions, oxygen ions and/or halogen ions.

18. The method as claimed in claim 1, wherein etching the material comprises performing a dry etching step wherein silicon is etched using HBr, Cl₂, HCl, SF₆ and/or NF₃ as etchant.

19. The method as claimed in claim 1, wherein etching the material comprises performing a dry etching method using a parallel plate reactor (RIE), inductive coupling (ICP), resonant excitation (ECR, helicon), or microwaves.

20. The method as claimed in claim 1, wherein the material comprises silicon of a substrate for the fabrication of DRAM chips or logic chips.
